(19) United States
(12) Patent Application Publication
(10) Pub. No.: US 2011/0034138 A1
(43) Pub. Date: Feb. 10, 2011

(54) TUNER AND BROADCAST RECEIVER HAVING THE SAME

(76) Inventor: Yeon Joo Park, Mapo-gu Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/672,648

(22) PCT Filed: Aug. 6, 2008
(86) PCT No.: PCT/KR2008/004575

§ 371 Date: Feb. 8, 2010

(30) Foreign Application Priority Data
Aug. 9, 2007 (KR) 1020070080186

(51) Int. Cl. H04B 17/02; H03J 5/00

(52) U.S. Cl. 455/133; 334/39

(57) ABSTRACT

Provided are a tuner and a broadcast receiver having the same. The tuner comprises a first signal receiver, a second signal receiver, a signal converter, and a signal processor. The first signal receiver receives a first signal. The second signal receiver receives a second signal. The signal converter converts the second signal into a signal in a frequency band of the first signal. The signal processor processes an output signal of the first signal receiver or the signal converter.

### TECHNICAL FIELD

Embodiments relate to a tuner and a broadcast receiver having the same.

### BACKGROUND ART

As broadcasting media has been digitalized, terrestrial and satellite digital multimedia broadcastings have been serviced. Recently, as the cable broadcasting employs a digital system, the digital multimedia broadcasting is more actively serviced.

As the media utilizing an encoding widely spread, the digitalization of the broadcasting signal will accelerate the communication-computer-broadcasting convergence, enable the internationalization and multi-channel of the single multifunctional media, and provide a variety of data services.

### DISCLOSURE OF INVENTION

### Technical Problem

Embodiments provide a tuner for converting one of received signals in different bands into a signal in other band, and processing the signal, and a broadcast receiver having the same.

Embodiments provide a tuner that demodulates a selected signal when the selected signal is in a first signal band, and when the selected signal is in a second signal band, converts the selected signal into a signal in the first signal band, and then demodulates the signal, and a broadcast receiver having the same.

Embodiments provide a tuner that can convert a terrestrial wave signal into a signal in a satellite band to demodulate the signal, and a broadcast receiver having the same.

Embodiments provide a tuner that can convert a satellite signal into a signal in a terrestrial wave band to demodulate the signal, and a broadcast receiver having the same.

Embodiments provide a tuner that can activate a transmission path of a selected signal, and an element, and a broadcast receiver having the same.

### Technical Solution

An embodiment provides a tuner comprising: a first signal receiver receiving a first signal; a second signal receiver receiving a second signal; a signal converter converting the second signal into a signal in a frequency band of the first signal; and a signal processor processing an output signal of the first signal receiver or the signal converter.

An embodiment provides a tuner comprising: a signal receiver receiving a first signal and a second signal; a signal converter converting the first signal or the second signal; a first switch selecting an output path of the signal receiver or the signal converter according to a channel of a selected signal; and a signal processor processing an output signal of the first switch.

An embodiment provides a broadcast receiver comprising: a first signal receiver receiving a first signal; a second signal receiver receiving a second signal; a signal converter converting the second signal into a signal in a frequency band of the first signal; a first switch selecting an output path of the first signal receiver or the signal converter according to a channel of a selected signal; a signal processor processing an output signal of the first switch; and a controller controlling operations of the first signal receiver, the second signal receiver, and the signal processor according to channel selection.

The details of one or more embodiments are set forth in the accompanying drawings and the description below. Other features will be apparent from the description and drawings, and from the claims.

### ADVANTAGEOUS EFFECTS

An embodiment can prevent crosstalk between signals.

According to an embodiment, an instrumental shielding structure for preventing mutual crosstalk between signals in different bands does not need to be installed.

According to an embodiment, since a shielding structure such as a chassis does not need to be installed in order to prevent mutual crosstalk, the instrumental structure of a tuner can be simplified.

According to an embodiment, a tuner converts one of signals in different bands into a signal in other band, so that a circuit component of the tuner is simplified.

According to an embodiment, a tuner converts a signal in a ground wave band into a satellite signal to process the signal, so that a mixer oscillator phase looked loop (MOPLL) IC is not required and thus a circuit construction of the tuner can be simplified.

According to an embodiment, a tuner converts a satellite signal into a signal in a terrestrial wave band to process the signal, so that a zero intermediate frequency (ZIF) integrated circuit (IC) is not required and thus a circuit component of the tuner can be simplified.

### BRIEF DESCRIPTION OF THE DRAWINGS

FIG. 1 is a construction view of a broadcast receiver according to a first embodiment.

FIG. 2 is a construction view of a broadcast receiver according to a second embodiment.

FIG. 3 is a construction view of a broadcast receiver according to a third embodiment.

FIG. 4 is a circuit diagram of FIG. 3.

FIG. 5 is another circuit diagram of FIG. 3.

### BEST MODE FOR CARRYING OUT THE INVENTION

Hereinafter, embodiments are described with reference to the accompanying drawings.

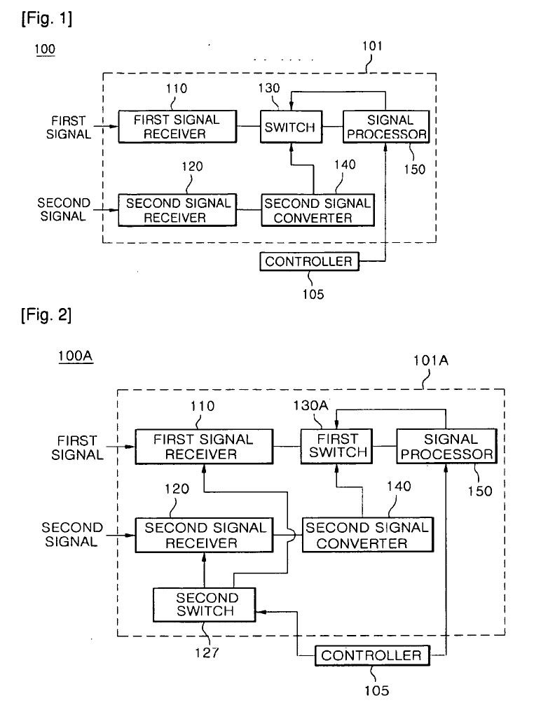

FIG. 1 is a construction view of a broadcast receiver according to a first embodiment.

Referring to FIG. 1, the broadcast receiver 100 comprises a tuner 101 and a controller 105. The tuner 101 comprises a first signal receiver 110, a second signal receiver 120, a switch 130, a second signal converter 140, and a signal processor 150.

The tuner 101 receives a first signal and a second signal. The first and second signals are broadcast signals in different bands. The tuner 101 selects broadcast signals received through a specific channel under control of the controller 105.

A first signal can be a satellite signal of 950-2150 MHz band, and a second signal can be a terrestrial wave signal of 50-860 MHz band. Alternatively, the first signal can be a terrestrial wave signal of 50-860 MHz band, and the second signal can be a satellite signal of 950-2150 MHz band.

The controller 105 receives various commands from a user, and controls an operation of the tuner 101 according to a channel selection command. The controller 105 may be or may not be comprised in the tuner 101.

The first signal receiver 110 of the tuner 101 passes signals of a first signal band among received signals, and amplifies the passed signals to a predetermined level to output the same. Here, the first signal receiver 110 can output the signals of the first signal band using a filter, and amplify the signals using a low noise amplifier.

The second signal receiver 120 of the tuner 101 passes signals of a second signal band among received signals, and amplifies the passed signals to a predetermined level to output the same. Here, the second signal receiver 120 can output the signal of the second signal band using a filter, and amplify the signals using a low noise amplifier.

The second signal converter 140 receives the second signal outputted from the second signal receiver 120 to convert the second signal into a frequency band of the first signal. That is, the second signal converter 140 converts the second signal into the frequency band of the first signal through a mixing operation of adding or subtracting a local frequency to and from the second signal.

When the second signal is a terrestrial wave signal of 50-860 MHz band, the second signal converter 140 can add a local frequency of about 900 MHz to the second signal to convert the second signal into a signal of 950-1760 MHz band. Alternatively, when the second signal is a satellite signal of 950-2150 MHz band, the second signal converter 140 can subtract a local frequency of about 900 MHz from the second signal to convert the second signal into a signal of 50-1250 MHz band. Also, the second signal converter 140 can output a converted signal in a desired frequency band through a filter.

The second signal converter 140 outputs the converted second signal to the switch 130.

The switch 130 selectively outputs a signals outputted from the first signal receiver 110 and the second signal converter 140 by control of the signal processor 150. The switch 130 selectively outputs only one of the first signal and the converted second signal. Here, the switch 130 can select a path of the first signal or the second signal in response to a control signal of the signal processor 150, or operate by control of the controller 105 according to a channel of a selected signal.

The signal processor 150 demodulates the signal outputted from the switch 130 by control of the controller 105. At this point, the signal processor 150 converts an input signal into an intermediate frequency signal that can be demodulated, and then demodulates the signal. Here, when the input signal is a satellite signal, the signal processor 150 converts the signal into a baseband signal or a ZIF signal, and then demodulates the same. At this point, the signal processor 150 can comprise a ZIF IC.

Also, when the input signal is a terrestrial wave signal, the signal processor 150 converts the signal into an IF signal, and then demodulates the signal. At this point, the signal processor 150 can comprise a mixer oscillator phase locked loop (MOPLL) IC.

According to the first embodiment, the tuner 101 converts one of signals of different bands into a signal in other band, so that a circuit component of the tuner 101 can be simplified. For example, the tuner 101 converts a terrestrial wave signal into a signal in a satellite band, so that an MOPLL IC can be removed. Alternatively, the tuner 101 converts a satellite signal into a signal in a terrestrial wave band to process the signal, so that a ZIF IC can be removed.

FIG. 2 is a construction view of a broadcast receiver according to a second embodiment. In describing the second embodiment, description of the same parts as those of the first embodiment are omitted.

Referring to FIG. 2, the broadcast receiver 100A comprises a tuner 101A and a controller 105. The tuner 101A comprises a first signal receiver 110, a second signal receiver 120, a first switch 130A, a second signal converter 140, a signal processor 150, and a second switch 127. The second switch 127 can be provided outside the tuner 101A.

The first switch 130A selects a path of a first signal or a second signal in response to a control signal of the signal processor 150. A signal of the selected path is outputted to the signal processor 150.

The second switch 127 controls the operations of the first signal receiver 110 and the second signal receiver 120 in response to a control signal of the controller 105. When a selected signal is a signal of a first channel, the controller 105 controls the second switch 127 to drive the first signal receiver 110. The first signal receiver 110 outputs a first signal. At this point, the second signal receiver 120 is turned off.

Also, when the selected signal is a signal of a second channel, the controller 105 controls the second switch 127 to drive the second signal receiver 120. The second signal receiver 120 outputs a second signal. At this point, the first signal receiver 110 is turned off.

The second embodiment selectively drives the first signal receiver 110 and the second signal receiver 120 according to a channel of a selected signal, thereby preventing crosstalk between signals of different bands. Also, since an instrumental shielding structure such as a chassis does not need to be installed around the tuner 101A, the instrumental structure of the tuner 101A can be simplified.

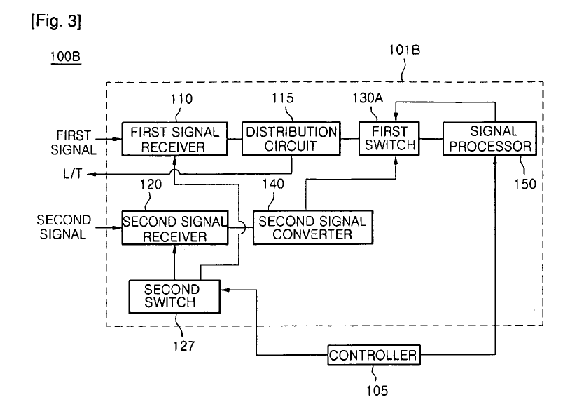

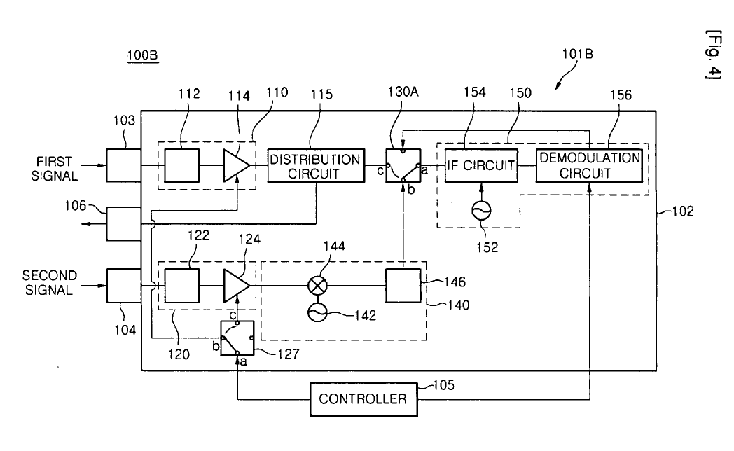

FIG. 3 is a construction view of a broadcast receiver according to a third embodiment. In describing the third embodiment, description of the same parts as those of the first embodiment are omitted.

Referring to FIG. 3, the broadcast receiver 100B comprises a tuner 101B and a controller 105. The tuner 101B comprises a first signal receiver 110, a distribution circuit 115, a second signal receiver 120, a first switch 130A, a second signal converter 140, a signal processor 150, and a second switch 127.

The distribution circuit 115 can be installed on an output path of a first signal. For example, the distribution circuit 115 is installed on an output path of the first signal receiver 110 to distribute the first signal and output a signal for a loop-through function. The distribution circuit 115 can be installed on an output path of a second signal and is not limited thereto.

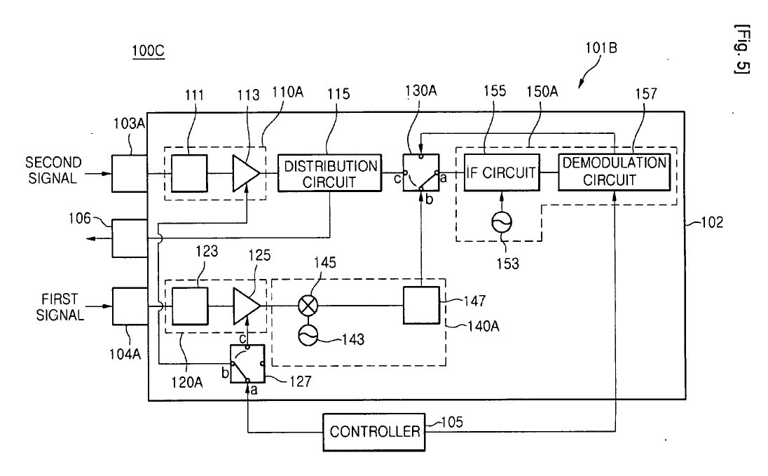

FIG. 4 is a circuit diagram of FIG. 3.

Referring to FIG. 4, the tuner 101B is received in a housing 102. A first signal input terminal 103, a second signal input terminal 104, and a loop-through output terminal 106 are provided to one side of the housing 102. Here, a satellite signal of 950-2150 MHz band is inputted to the first signal input terminal 103, and a terrestrial wave signal of 50-860 MHz band is inputted to the second signal input terminal 104.

The first signal receiver 110 of the tuner 101B comprises a first filter 112 and a first amplifier 114. The second signal receiver 120 comprises a second filter 122 and a second amplifier 124.

The first filter 112 of the first signal receiver 110 passes a frequency band of the first signal among signals received to the first signal input terminal 103. The first filter 112 can be realized using a band pass filter (BPF), for example. The first amplifier 114 amplifies and outputs first signals that have passed through the first filter 112. The first amplifier 114 can be realized using a low noise amplifier (LNA).

A second filter 122 of the second signal receiver 120 passes the frequency band of the second signal among signals received to the second signal input terminal 104. The second filter 122 can be realized using a band pass filter (BPF), for example. The second amplifier 124 amplifies and outputs second signals that have passed through the second filter 122. The second amplifier 124 can be realized using a low noise amplifier (LNA).

The first amplifier 114 of the first signal receiver 110, and the second amplifier 124 of the second signal receiver 120 are turned-on/off by the second switch 127 according to a channel of a selected signal.

The second signal converter 140 comprises a first oscillator 142, a mixer 144, and a third filter 146. The first oscillator 142 outputs a first local frequency, and the mixer 144 up-converts the second signal using the first local frequency to output the frequency band of the first signal. The third filter 146 passes the frequency band of the first signal among the up-converted second signals. The third filter 146 can be realized using a BPF.

Here, the second signal converter 140 receives a terrestrial wave signal of 50-860 MHz band and outputs a converted signal of 950-1760 MHz band. When the first oscillator 142 outputs a frequency of about 900 MHz, which is a first local frequency, to the mixer 144, the mixer 144 adds a terrestrial wave signal of 50-860 MHz band and the local frequency of about 900 MHz to output a converted signal of 950-1760 MHz band. The third filter 146 passes a signal of 950-2150 MHz band among the signals outputted from the mixer 144.

The first switch 130A selects a signal path by control of a demodulation circuit 156 of the signal processor 150.

The signal processor 150 comprises a second oscillator 152, an IF circuit 154, and the demodulation circuit 156. The second oscillator 152 generates a second local frequency, and the IF circuit 154 converts a signal output from the first switch 130A into an IF signal using the second local frequency, and outputs the same. That is, the IF circuit 154 converts the input first signal or the converted second signal into a baseband signal or a ZIF signal using the second local frequency, and outputs the same. The IF circuit 154 serves as the mixer, and the IF circuit 154 and the second oscillator 152 can be realized using a ZIF IC.

For example, the first signal of 950-2150 MHz band is inputted to the IF circuit 154, or the converted second signal of 950-1760 MHz band is inputted to the IF circuit 154. The second oscillator 152 generates the second local frequency of about 950-2150 MHz. The IF circuit 154 mixes the first signal or the converted second signal with the second local frequency to output a baseband signal or a ZIF signal.

The demodulation circuit 156 demodulates a signal outputted from the IF circuit 154 to output a transport stream.

A specific operation of receiving a signal is described in the following.

The controller 105 receives a channel selection signal, and analyzes the received channel signal. The controller 105 transfers a control signal to the second switch 127 and the demodulation circuit 156 according to the analyzed channel signal. The demodulation circuit 156 controls a reception path of the first switch 130A.

When a signal of a first channel is received, the controller 105 controls the path a-b of the second switch 127 to drive the first amplifier 114 of the first signal receiver 110.

When a signal of a second channel is received, the controller 105 controls the path a-c of the second switch 127 to drive the second amplifier 124 of the second signal receiver 120.

An operation of receiving the first signal is described below. When satellite signals are received to the first signal input terminal 103 of the tuner 101B, the first filter 112 of the first signal receiver 110 passes the frequency band of the first signal among received signals, and the first amplifier 114 amplifies and outputs the first signal. The first signal passes through the distribution circuit 115, and is inputted the first switch 130A. The first switch 130A is switched to a first path a-c in response to a control signal of the demodulation circuit 156, and outputs the first signal to the signal processor 150. The IF circuit 154 of the signal processor 150 converts the first signal, which is the satellite signal, into a ZIF signal. The demodulation circuit 156 demodulates the ZIF signal into a digital signal.

An operation of receiving the second signal is described below. When terrestrial wave signals are received to the second signal input terminal 104 of the tuner 101B, the second filter 122 of the second signal receiver 120 passes the frequency band of the second signal among received signals, and the second amplifier 124 amplifies and outputs the second signal. The mixer 144 of the second signal converter 140 up-converts the second signal using the first local frequency to convert the second signal into the frequency band of the first signal. The third filter 146 filters the converted second signal and outputs the signal to the first switch 130A. The first switch 130A is switched to a second path of a-b in response to a control signal of the demodulation circuit 156, and outputs the converted second signal to the signal processor 150. The IF circuit 154 of the signal processor 150 converts the converted second signal, which is the terrestrial wave signal, into a ZIF signal using the second local frequency. The demodulation circuit 156 demodulates the ZIF signal into a digital signal. According to this circuit component, since an MOPLL IC is not required separately, the circuit component of the tuner 101B can be simplified. Also, a separate structure for shielding electromagnetic wave does not need to be installed to the housing 102 of the tuner 101B.

FIG. 5 is another circuit diagram of FIG. 3. In FIG. 5, descriptions of the same parts as those of FIG. 4 are omitted, and description is made briefly.

Referring to FIG. 5, a tuner 101B of a broadcast receiver 100C comprises a first signal converter 140A converting a first signal into the frequency band of a second signal.

The tuner 101B is received in a housing 102. A second signal input terminal 103A, a first signal input terminal 104A, and a loop-through output terminal 106 are provided to one side of the housing 102. Here, a satellite signal in a band of about 950-2150 MHz is inputted to the second signal input terminal 103A, and a terrestrial wave signal in a band of about 50-860 MHz is inputted to the first signal input terminal 104A.

The second signal receiver 110A of the tuner 101B comprises a second filter 111 and a second amplifier 113. The first signal receiver 120A comprises a first filter 123 and a first amplifier 125.

The second filter 111 of the second signal receiver 110A passes the frequency band of a second signal among signals received to the second signal input terminal 103A. The second filter 111 can be realized using a band pass filter (BPF), for example. The second amplifier 113 amplifies and outputs second signals that have passed through the second filter 111. The second amplifier 113 can be realized using a low noise amplifier (LNA).

A first filter 123 of the first signal receiver 120A passes the frequency band of the first signal of signals received to the first signal input terminal 104A. The first filter 123 can be realized using a band pass filter (BPF), for example. The first amplifier 125 amplifies and outputs first signals that have passed through the first filter 123. The first amplifier 125 can be realized using a low noise amplifier (LNA).

The second amplifier 113 of the second signal receiver 110A, and the first amplifier 125 of the first signal receiver 120A are selectively driven by the second switch 127 according to a channel of a selected signal.

The first signal converter 140A comprises a first oscillator 143, a mixer 145, and a third filter 147. The first oscillator 143 outputs a first local frequency, and the mixer 145 down-converts the first signal using the first local frequency to output the frequency band of the second signal. The third filter 147 passes the frequency band of the second signal in the band of the converted first signal. The third filter 147 can be realized using a BPF.

The first signal converter 140A converts a satellite signal of 950-2150 MHz band into a signal of 50-1250 MHz band. At this point, when the first oscillator 143 outputs a first local frequency of about 900 MHz, which is the first local frequency, to the mixer 145, the mixer 145 subtracts a first local frequency of about 900 MHz from the satellite signal of 950-2150 MHz band to convert the signal into a signal of 50-1250 MHz band. The third filter 147 passes a signal of 50-860 MHz band among signals outputted from the mixer 145.

The first switch 130A selects a signal path by control of a demodulation circuit 157 of a signal processor 150A.

The signal processor 150A comprises a second oscillator 153, an IF circuit 155, and the demodulation circuit 157. The second oscillator 153 generates a second local frequency, and the IF circuit 155 converts a signal from the first switch 130A into an IF signal using a second local frequency, and outputs the same. That is, the IF circuit 155 converts the converted first signal or the second signal into an IF signal using the second local frequency, and outputs the same. For example, the converted first signal or the second signal of 50-860 MHz band is inputted, and the second oscillator 153 generates the second local frequency. The IF circuit 155 mixes the converted first signal or the second signal with the second local frequency to output an IF signal.

The demodulation circuit 157 demodulates a signal outputted from the IF circuit 155 to output a transport stream. The IF circuit 155 serves as a mixer. The IF circuit 155, the second oscillator 153, and a phase locked loop (PLL) (not shown) can be realized using a MOPLL IC.

An operation of receiving the second signal is described below. When terrestrial wave signals are received to the second signal input terminal 103A of the tuner 101B, the second filter 111 of the second signal receiver 110A passes the frequency band of the second signal of received signals, and the second amplifier 113 amplifies and outputs the second signal. The second signal passes through a distribution circuit 115 and is inputted to the first switch 130A. The first switch 130A is switched to a first path of a-c in response to a control signal of the demodulation circuit 157, and outputs the second signal to the signal processor 150A. The IF circuit 155 of the signal processor 150A converts the second signal, which is a satellite signal, into an IF signal. The demodulation circuit 157 demodulates the IF signal into a digital signal.

An operation of receiving the first signal is described below. When satellite signals are received to the first signal input terminal 104A of the tuner 101B, the first filter 123 of the first signal receiver 120A passes the frequency band of the first signal of received signals, and the first amplifier 125 amplifies and outputs the first signal. The mixer 145 of the first signal converter 140A down-converts the first signal into the frequency band of the second signal using the first local frequency. The third filter 147 passes the converted first signal to output the same to the first switch 130A. The first switch 130A is switched to a second path of a-b in response to a control signal of the demodulation circuit 157, and outputs the converted first signal to the signal processor 150A. The IF circuit 155 of the signal processor 150A converts the converted first signal, which is the satellite signal, into an IF signal using the second local frequency. The demodulation circuit 157 demodulates the IF signal into a digital signal.

According to this circuit component, since a ZIF IC converting a satellite signal into a ZIF signal is not required separately, the circuit component of the tuner 101B can be simplified. Also, a separate structure for shielding electromagnetic wave does not need to be installed to the housing 102 of the tuner 101B.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

An embodiment can prevent crosstalk between signals.

According to an embodiment, an instrumental shielding structure for preventing mutual crosstalk between signals in different bands does not need to be installed.

According to an embodiment, since a shielding structure such as a chassis does not need to be installed in order to prevent mutual crosstalk, the instrumental structure of a tuner can be simplified.

According to an embodiment, a tuner converts one of signals in different bands into a signal in other band, so that a circuit component of the tuner is simplified.

According to an embodiment, a tuner converts a signal in a ground wave band into a satellite signal to process the signal, so that a mixer oscillator phase looked loop (MOPLL) IC is not required and thus a circuit construction of the tuner can be simplified.

According to an embodiment, a tuner converts a satellite signal into a signal in a terrestrial wave band to process the signal, so that a zero intermediate frequency (ZIF) integrated circuit (IC) is not required and thus a circuit component of the tuner can be simplified.

1. A tuner comprising:
a first signal receiver receiving a first signal;
a second signal receiver receiving a second signal;
a signal converter converting the second signal into a signal in a frequency band of the first signal; and
a signal processor processing an output signal of the first signal receiver or the signal converter.

2. The tuner according to claim 1, comprising a first switch selecting an output path of the first signal receiver or the signal converter.

3. The tuner according to claim 1, comprising a second switch driving the first signal receiver or the second signal receiver according to a selected signal.

4. The tuner according to claim 1, wherein the first signal and the second signal comprise broadcast signals in different bands.

5. The tuner according to claim 2, comprising a distribution circuit connected between the first signal receiver and the first switch.

6. The tuner according to claim 1, wherein the first signal receiver comprises:
a first filter passing a frequency band of the first signal; and
a first amplifier amplifying a signal that has passed through the first filter, the second signal receiver comprises:
a second filter passing a frequency band of the second signal; and
a second amplifier amplifying a signal that has passed through the second filter.

7. The tuner according to claim 1, wherein the signal converter comprises:
a first oscillator outputting a first local frequency; and
a mixer mixing the first local frequency of the first oscillator with the second signal from the second signal receiver to convert the second signal into a frequency band of the first signal.

8. The tuner according to claim 7, wherein the mixer adds or subtracts the first local frequency to and from the second signal.

9. The tuner according to claim 1, wherein the signal processor comprises:
a second oscillator outputting a second local frequency;
an intermediate frequency circuit converting the first signal or a signal from the signal converter into an intermediate frequency using the second local frequency; and
a demodulation circuit demodulating a signal from the intermediate frequency circuit.

10. The tuner according to claim 1, wherein the signal processor comprises a zero intermediate frequency integrated circuit or a mixer oscillator phase locked loop integrated circuit.

11. A tuner comprising:
a signal receiver receiving a first signal and a second signal;
a signal converter converting the first signal or the second signal;
a first switch selecting an output path of the signal receiver or the signal converter according to a channel of a selected signal; and
a signal processor processing an output signal of the first switch.

12. The tuner according to claim 11, wherein the signal receiver comprises a first signal receiver and a second signal receiver, and each of the first and second signal receivers comprises a band pass filter and an amplifier.

13. The tuner according to claim 12, comprising a second switch controlling driving of the amplifier of the first signal receiver or the second signal receiver depending on a selected signal.

14. The tuner according to claim 11, wherein each of the first signal and the second signal comprises a broadcast signal in one of 950-2150 MHz band and 50-860 MHz band, and the first signal and the second signal comprise signals in different bands.

15. The tuner according to claim 11, comprising a distribution circuit connected between the signal receiver and the first switch, and distributing the first signal to perform a loop-through function.

16. The tuner according to claim 11, wherein the signal converter comprises:
an oscillator generating a local frequency; and
a mixer mixing the second signal with the local frequency to convert the second signal into a frequency band of the first signal.

17. A broadcast receiver comprising:
a first signal receiver receiving a first signal;
a second signal receiver receiving a second signal;
a signal converter converting the second signal into a signal in a frequency band of the first signal;
a first switch selecting an output path of the first signal receiver or the signal converter according to a channel of a selected signal;
a signal processor processing an output signal of the first switch; and
a controller controlling operations of the first signal receiver, the second signal receiver, and the signal processor depending on channel selection.

18. The broadcast receiver according to claim 17, comprising a second switch driving the first signal receiver or the second signal receiver in response to a control signal of the controller.

19. The broadcast receiver according to claim 17, wherein one of the first signal and the second signal comprises a satellite broadcast signal, and the other comprises a terrestrial wave broadcast signal.

20. The broadcast receiver according to claim 17, wherein the signal converter comprises:
a first oscillator outputting a first local frequency; and
a mixer mixing the first local frequency of the first oscillator with a signal from the second signal receiver to convert the signal into a frequency band of the first signal.
